(19) United States
(12) Patent Application Publication
(10) Pub. No.: US 2024/0006203 A1
(43) Pub. Date: Jan. 4, 2024

(54) CHAMBER LINER FOR SEMICONDUCTOR PROCESSING

(71) Applicant: Taiwan Semiconductor Manufacturing Company, Hsinchu (TW)

(72) Inventors: Chien-Liang Chen, New Taipei (TW); Wei-Da Chen, Hsinchu (TW); Yu-Ning Cheng, Taipei (TW)

(21) Appl. No.: 17/854,091

(22) Filed: Jun. 30, 2022

(51) Int. Cl. H01L 21/67; C23C 16/44; H01J 37/32

(52) U.S. Cl. CPC H01L 21/67207; C23C 16/4404; H01J 37/32458; H01L 21/67069

(57) ABSTRACT

A chamber liner for a semiconductor process chamber. The chamber liner includes an outer sidewall having a first circumference, and an inner sidewall have a second circumference that is less than the first circumference. The chamber liner also includes a chamber liner fence that is positioned between the outer sidewall and the inner sidewall. The chamber liner fence includes a first zone having one or more first zone openings, a second zone having one or more second zone openings, and a third zone having one or more third zone opening. The chamber liner further includes a split door positioned in the outer sidewall. Each of the first, second, and third zones have different widths, with the width of the third zone opening less than the width of the second zone opening, and the second zone opening less than or equal to the width of the first zone opening.

### BACKGROUND

The following relates to systems and components for control of gas flow within a semiconductor process chamber. Integrated circuits are formed on a semiconductor substrate, which is typically comprised of silicon. Such formation involves sequential deposition of various materials in layers or films, e.g. conductive and nonconductive layers. Deposition and etching processes may be used to form geometric patterns in the layers or vias for electrical contact between the layers. Etching processes may include “wet” etching, wherein a solvent or chemical reagent is used, or “dry” etching, wherein plasma is used. Such processes utilize a gas or fluid for etching, and flow of the gas or fluid impacts wafer quality and uniformity.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an exemplary semiconductor manufacturing apparatus in accordance with some embodiments.

FIG. 2 illustrates an isometric view of a chamber liner in accordance with some embodiments.

FIGS. 3A-3D are close-up views of a chamber liner in accordance with some embodiments.

FIG. 4A-4D are top, cross-sectional, side, and bottom views of a chamber liner in accordance with some embodiments.

FIGS. 5A-5C are illustrative views of a chamber liner in accordance with an alternate embodiment.

FIGS. 6A-6B are illustrative fluid diagrams of a chamber liner in accordance with some embodiments.

FIG. 7 is an expanded view of a semiconductor manufacturing apparatus in accordance with some embodiments.

FIG. 8 is a three-dimensional cross-sectional view of a semiconductor manufacturing apparatus in accordance with some embodiments.

FIG. 9 is a method for processing a wafer utilizing a chamber liner in accordance with some embodiments.

FIG. 10 is a method for fabricating a chamber liner in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

Dry etching processes, also referred to as plasma etching processes, are carried out to etch various films at various stages of the semiconductor manufacturing operation and produce various device features. Multiple plasma etching operations are sometimes used during fabrication of a semiconductor device. Various types of plasma etching processes are known in the art, including plasma etching, reactive ion (RI) etching and reactive ion beam etching. In each of these plasma processes, a gas is first introduced into a reaction chamber and then plasma is generated from the gas. This is accomplished by dissociation of the gas into ions, free radicals and electrons by using an RF (radio frequency) generator, which includes one or more electrodes. The electrodes are accelerated in an electric field generated by the electrodes, and the energized electrons strike gas molecules to form additional ions, free radicals and electrons, which strike additional gas molecules, and the plasma eventually becomes self-sustaining. The ions, free radicals and electrons in the plasma react chemically with the layer material on the semiconductor wafer to form residual products which leave the wafer surface and thus, etch the material from the wafer.

In the fabrication of semiconductor devices, particularly sub-micron scale semiconductor devices, profiles obtained in the etching process are very important. Careful control of a surface etch process is therefore necessary to ensure directional etching. In conducting an etching process, when an etch rate is considerably higher in one direction than in the other directions, the process is called anisotropic. A reactive ion etching (RIE) process assisted by plasma is frequently used in an anisotropic etching of various material layers on top of S semiconductor substrate. In plasma enhanced etching processes, the etch rate of a semiconductor material is frequently larger than the sum of the individual etch rates for ion sputtering and individual etching due to a synergy in which chemical etching is enhanced by ion bombardment.

To avoid subjecting a semiconductor wafer to high-energy ion bombardment, the wafer may also be placed downstream from the plasma and outside the discharge area. Downstream plasma etches more in an isotropic manner since there are no ions to induce directional etching. The downstream reactors are frequently used for removing resist or other layers of material where patterning is not critical. In a downstream reactor, radio frequency may be used to generate long-lived radioactive species for transporting to a wafer surface located remote from the plasma. During these etching processes, gas and etch products are introduced and produced, with the flow of such gas and etch products being impacted by the location of the wafer within the chamber, the chamber liner, and the components supporting the wafer, such as a cantilever. Such impacted flow can deleteriously affect wafer quality, uniformity, critical depth, and the like.

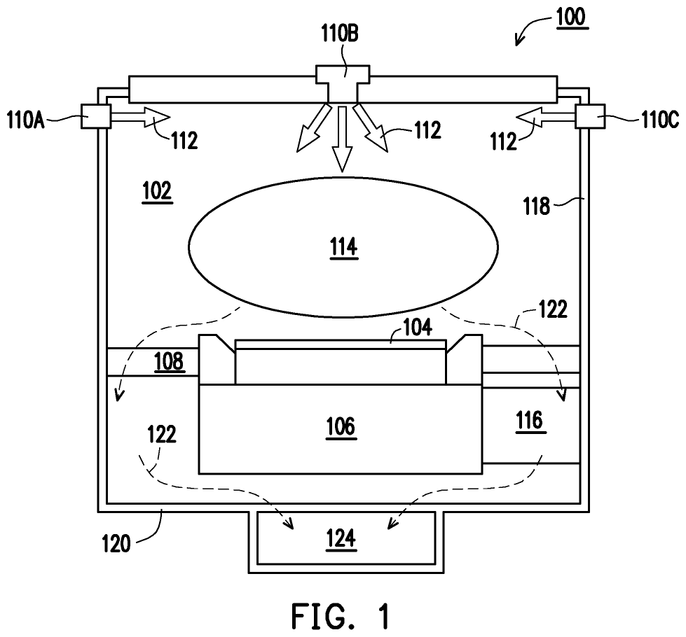

Turning now to FIG. 1, there is shown a semiconductor manufacturing apparatus 100 in accordance with one embodiment of the subject application. As illustrated in FIG. 1, the semiconductor manufacturing apparatus 100 includes a process chamber 102 for accommodating a wafer 104 during operation of the apparatus 100. An electrode housing bowl 106 is positioned within the chamber 102 and configured to hold the wafer 104 therein. In some embodiments, the electrode housing bowl 106 includes an electrostatic chuck (ESC), a vacuum component, a heater, and/or other mechanism, as well be appreciated by those skilled in the art. In such embodiments, the electrode housing bowl 106 is configured to secure the wafer 104 in a position for processing during operations of the semiconductor manufacturing apparatus 100.

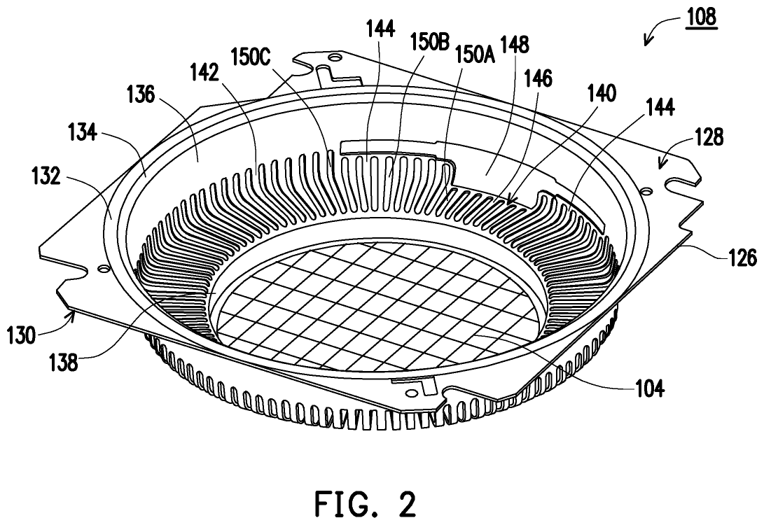

Surrounding the wafer 104 secured to the electrode housing bowl 106 within the process chamber 102 is a chamber liner 108, illustrated more fully in FIGS. 2-4D, below. In some embodiments, the chamber liner 108 is configured to improve edge flow uniformity from the asymmetric flow pattern of gas 112 within the process chamber 102. Accordingly, the chamber liner 108 utilized in the process chamber 102 of FIG. 1 may be implemented with a progressive fence design, as illustrated in FIGS. 2-4D. In some embodiments, the chamber liner 108 is constructed of anodized aluminum (cast, stamped, milled, etc.) and Y-coated with, for example and without limitation, YF₃, YOF, YAG (Y₃Al₅O₁₂), or the like.

The electrode housing bowl 106 is depicted in FIG. 1 as being supported within the process chamber 102 by a cantilever 116, extending perpendicularly from an inner chamber wall 118 of the process chamber 102 to the center of the chamber. It will be appreciated by those skilled in the art the depiction of the cantilever 116 extending perpendicularly from at least one inner chamber wall 118 of the process chamber 102 is intended as an example only. The cantilever 116 may be attached to any portion of the inner chamber wall 118 of the process chamber 102 in accordance with the various embodiments disclosed herein. In some embodiments contemplated herein, in addition to support, power and controls for the electrode housing bowl 106 may be routed through the cantilever 116.

As shown in FIG. 1, the cantilever 116 supports the electrode housing bowl 106 above a bottom 120 of the chamber 102. Gas 112, supplied from an external source, flows into the interior of the chamber 102 via gas inlets 110A, 1108, and 110C. It will be understood that the depicting of three gas inlets 110A-C is intended as an example, and the semiconductor manufacturing apparatus 100 may include one, two, three, four, five or more inlets to enable gas 112 to enter the chamber 102. In some embodiments, the gas 112 introduced into the chamber 102 is ignited by a power source such as a radio frequency (RF) generator to generate the plasma 114. The electrode housing bowl 106 may include an electrode (not shown) configured to ignited and sustain a plasma 114 reaction within the chamber 102. The plasma 114 may interact with deposition film on the wafer during a dry etch process. The gas 112 may include, for example and without limitation, CₓH_{y}F_{z} (x,y,z): 0˜6, He, Ar, F₂, Cl₂, O₂, N₂, H₂, HBr, HF, NF₃, SF₆, or the like.

The gas 112, energized via a coil (not shown) is introduced above the wafer 104 to generate ionized particles. These particles are dropped on the top surface of the wafer 104 and react with the deposited film. Some inert gases, such as nitrogen, argon, or helium may be introduced into the process chamber 102 via gas inlets 110A, 1108, or 110C as a carrier gas to distribute the ionized particles more evenly in the chamber 102. It will be appreciated that inert gas may be used in plasma etching as a diluent and a plasma stabilizer. Diluents may provide a process control variable. For example, an inert gas may be added to increase a total pressure while keeping partial pressures of other gases constant. It may further be appreciated that some gas species may improve the energy transfer from “hot” electrons to reactive gas molecules. Etch products 122, such as, for example and without limitation FCN, COₓ, (x: 1˜2), SIClₓ (x: 1˜4), SiFₓ (x: 1˜4), may be removed from the chamber 102 via a gas removal mechanism, shown in FIG. 1 as the pump 124. It will be appreciated that the location of the pump 124 depicted in FIG. 1 is intended as a non-limiting example of the location of the pump 124 relative to the process chamber 102. The skilled artisan will appreciate that placement of the pump 124 with respect to the chamber 102 may depend upon the type of process chamber, the materials being pumped, the location of the electrode housing bowl 106, the design of the chamber liner 108, the location of the cantilever 116, the location of outlets in the chamber 102, any myriad other factors.

Turning now to FIG. 2, there is shown an isometric view of a chamber liner 108 in accordance with one exemplary embodiment of the subject application. As illustrated in FIG. 2, the chamber liner 108 is generally cylindrical in shape, and includes an outer flange 126, having a top surface 128 and a bottom surface 130. In some embodiments, the bottom surface 130 of the outer flange 126 engages a top of the process chamber 102, supporting the chamber liner 108 therein. In accordance with other embodiments, the outer flange 126 is positioned around a periphery of the chamber liner 108, forming a rectangular shape therearound. It will be appreciated that the various slots, holes, etc., of the outer flange 126 may be altered dependent upon the process chamber 102 into which the chamber liner 108 is inserted. In accordance with some embodiments, the chamber liner 108 may be implemented with external dimensions in the range of about 300 mm to 800 mm. According to other embodiments, the chamber liner 108 may be implemented with internal dimensions in the range of about 250 mm to 600 mm.

Positioned within the outer flange 126 is a top chamber junction area 132, configured to engage a top surface of the 102. In some embodiments, the top chamber junction area 132 runs circumferentially around the chamber liner 108 and is coupled to an electrical contact area 134, shown in FIG. 2 as in contact with the top chamber junction area 132 and an outer sidewall 132 of the chamber liner 108.

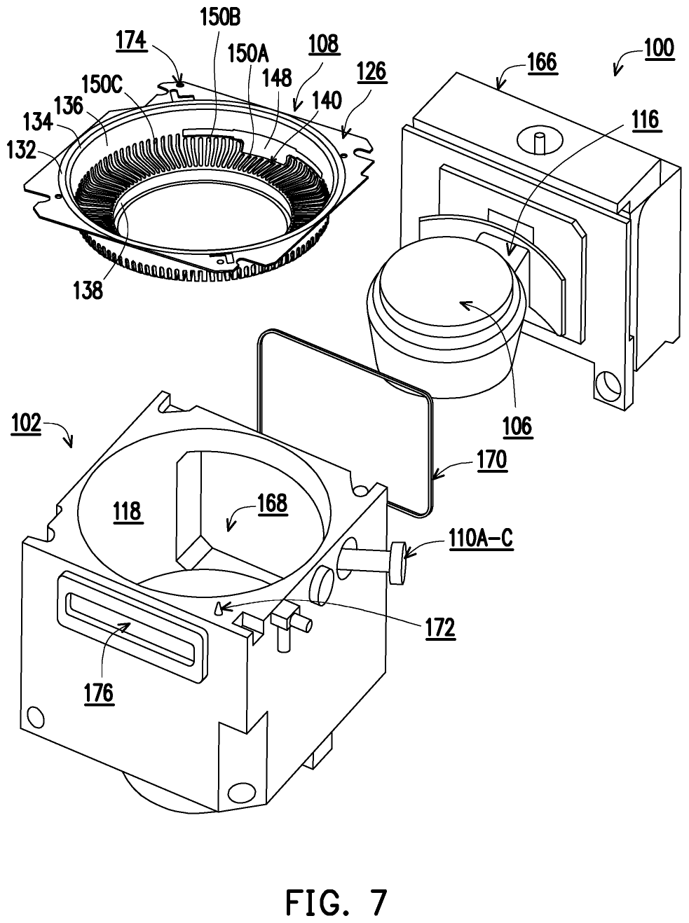

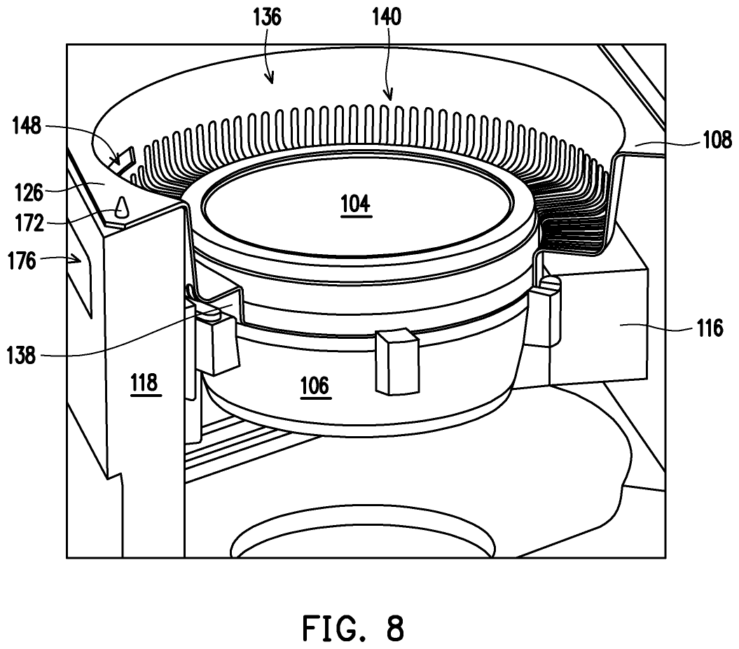

The outer sidewall 136 is illustrated in FIG. 2 as extending substantially perpendicularly downward from the outer flange 126 to an inner sidewall 138. In some embodiments, the outer sidewall 136 is coupled to the inner sidewall 138 via chamber liner fence 140. As shown, the outer sidewall 136 has a larger circumference than the inner sidewall 138. In some embodiments, the outer sidewall 136 has a circumference configured to engage an opening in the top of the process chamber 102 (illustrated more fully in FIGS. 7-8). The inner sidewall 138 has a circumference that is preferably configured to engage the outer circumference of the electrode housing bowl 106. In some embodiments, the chamber liner fence 140, comprises a peripheral fence opening area 142, a middle fence opening area 144, and a central fence opening area 146. In accordance with some embodiments, the thickness of the chamber liner fence 140 may be in the range of about 1 mm to 20 mm.

As illustrated in FIG. 2, the chamber liner fence 140 begins parallel with the outer sidewall 136 and curves inward to the inner sidewall 138. In accordance some embodiments, the outer sidewall 136 includes a portion of the chamber liner fence 140, particularly the peripheral fence opening area 142 which extends along a portion of the outer sidewall 136 to inner sidewall 138 as shown in FIG. 2. In the illustration of FIG. 2, the chamber liner 108 further includes a split door 148 positioned on one side of the chamber liner 108 in proximity to the peripheral fence opening area 144 and the central fence opening area 146. In accordance with some embodiments, the split door 148 is positioned opposite the cantilever 116, aligning with a wafer input slot (not shown) to enable the wafer 104 to ingress and egress the process chamber 102. An exemplary illustration of this alignment is provided in FIGS. 7 and 8, discussed in greater detail below. It will be appreciated that in some embodiments, e.g., when no wafer input slot is present, the split door 148 of the chamber liner 108 may be positioned above the cantilever 116 to enable proper fluid control of the gas 112, as discussed herein.

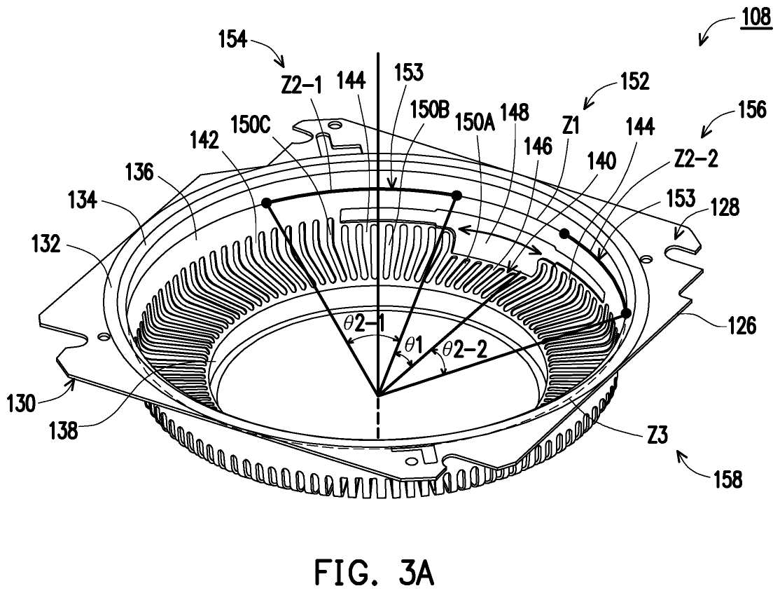

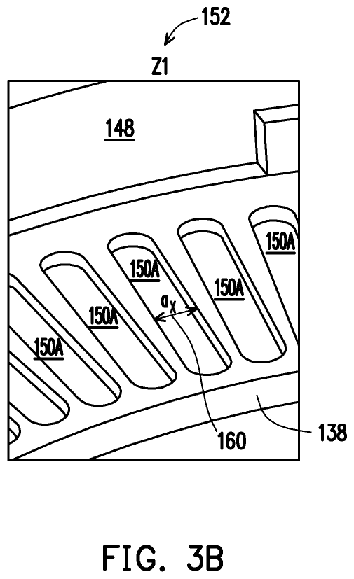

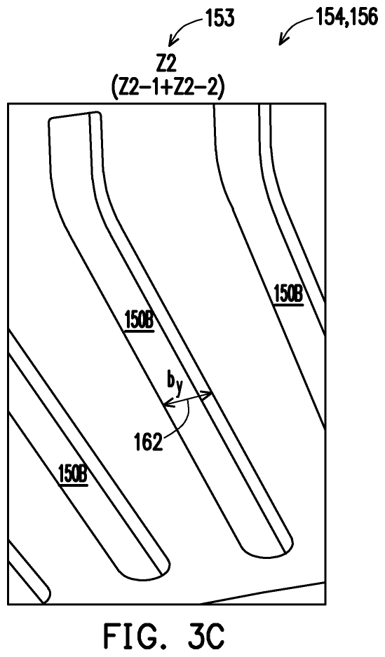

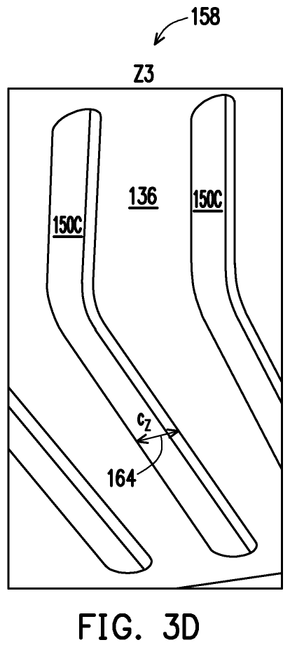

In accordance with some embodiments, the chamber liner fence 140 comprises a plurality of fence openings 150A, 150B, 150C, varying in size and/or shape. The aforementioned variation will be better appreciated in accordance with FIGS. 3A-3D. FIG. 3A illustrates the chamber liner 108 segmented into three distinct zones, each when combined together form the chamber liner 108. Zone 1 (Z1) 152, which corresponds to the central fence opening area 146 and includes fence openings 150A; Zone 2-1 (Z21) 154, which corresponds to a first portion of the middle fence opening area 144 and includes fence openings 150B; Zone 2-2 (Z22) 156, which corresponds to a second portion of the middle fence opening area 144 and includes fence openings 150B; and Zone 3 (Z3) 158, which corresponds to the peripheral fence opening area 142 and includes fence openings 150C. As used herein, Zone 2 153 corresponds to Zone 2-1 154 and Zone 2-2 153 collectively, wherein each of Zone 2-1 154 and Zone 2-2 153 utilize the fence openings 150B as illustrated in FIG. 3C, discussed below. In accordance with some embodiments, the chamber liner fence 140 may be implemented with a distribution circumference range of Z1+Z2−1+Z2−2; 0.1 mm<Z1, Z2<1060 mm. In such embodiments, the zones Z1, Z2−1 and Z2−2 154-158 may be implemented such that Angle: 1 degree<e1+e2−1+e2−2<180 degree, as illustrated in FIG. 3A.

A close-up view of a portion of Zone 1 (Z1) 152 is shown in FIG. 3B to illustrate the fence openings 150A disposed therein. As depicted in FIG. 3B, each fence opening 150A has a width aₓ 160. FIG. 3C provides a close-up view of a portion of Zone 2-1 (Z2−1) 154 and/or Zone 2-2 (Z2−2) 156 to illustrate the fence openings 150B contained in those zones 154-156. Each fence opening 150B in the illustrative example of FIG. 3C is depicted as having a width by 162. Similarly, FIG. 3D provides a close-up view of a portion of Zone 3 (Z3) 158 to illustrate the fence openings 150C contained in Zone 3 (Z3) 158. Each fence opening 150C in the illustrative example of FIG. 3D is depicted as having a width c_{z} 164. In accordance with some embodiments, “x” is the number of openings 150A in Z1 152; “y” is the number of openings 150B in Z2 (i.e., Z2−1+Z2−2) 156-158; and “z” is the number of openings 150C in Z3 158, such that the number of each type of opening 150A-150C in the chamber fence 140 may range from 1˜70650.

In accordance with some embodiments, the fence opening (150A-C) width (160-164) may be implemented as: 0.1 mm<c_{z}<b_{y}≤aₓ<100 mm (aₓ in Z1; b_{y} in Z2; c_{z} in Z3). Further, according to some embodiments, the fence opening width near the center (e.g., the width aₓ 160) may be larger than or equal to the fence gap width gradually moving away from the center (e.g., widths by 162 and c_{z} 164), wherein the center corresponds to the center of the split door 148. Likewise, the fence opening width (b_{y}) in Zone 2 153 (i.e., Z2−1, Z2−2) 154-156 may be larger than or equal to the width gap c_{z} 164 of Zone 3 (Z3) 158. It will be appreciated that the sizing of the widths 160-164 in the aforementioned manner balances the flow of gas 112 through the chamber liner 108. In some embodiments, the fence openings 150A-150C may be implemented with rounded or perpendicular edges and/or corners, as illustrated in FIGS. 3A-3D, and extend straight or substantially straight from the outer sidewall 136 to the inner sidewall 138. It will be appreciated that the ranges described above are intended solely as examples of values, and other widths may also be utilized in accordance with the systems and methods set forth herein.

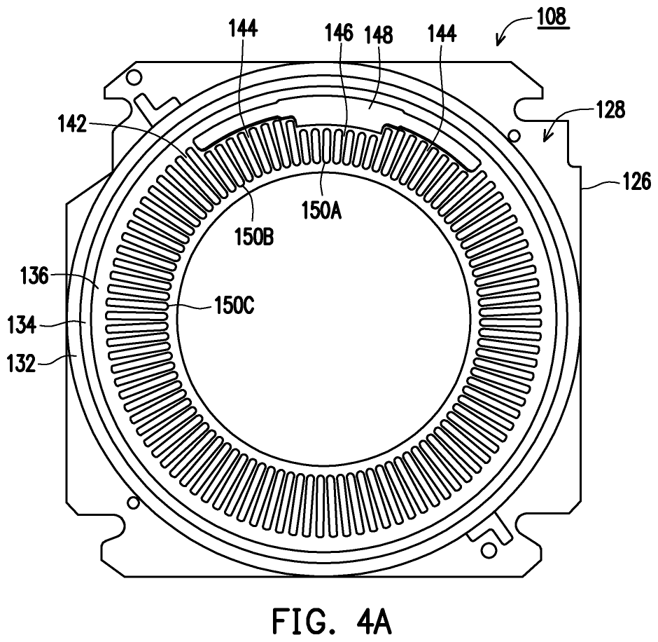

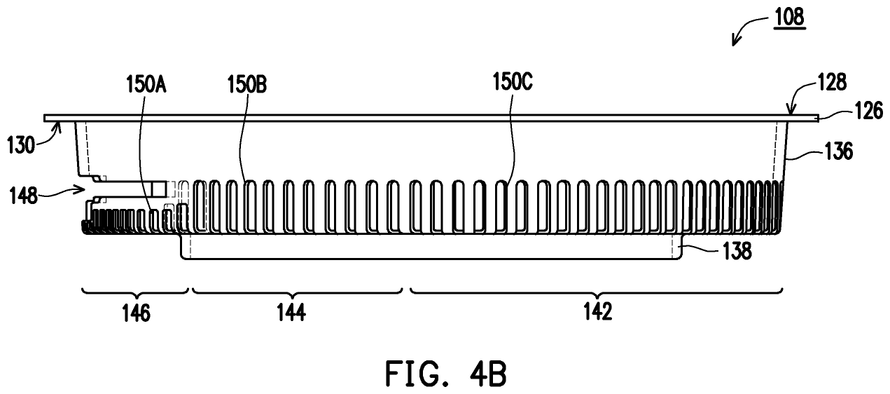

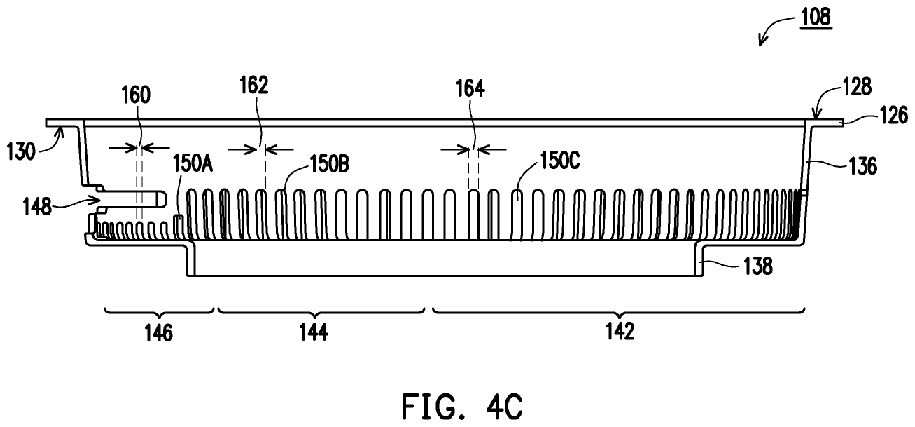

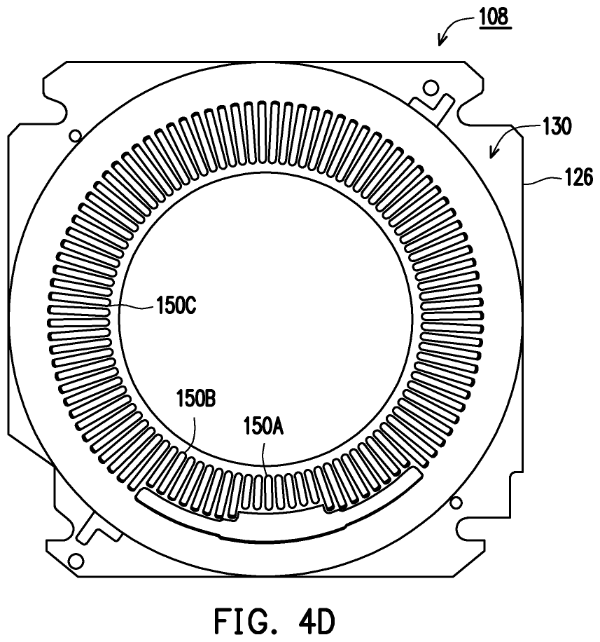

Turning now to FIGS. 4A-4D, there are shown top, cross-sectional, side, and bottom views of a chamber liner 108 in accordance with one embodiment of the subject application. As shown in FIG. 4A, the top of the chamber liner 108 includes a plurality of fence openings 150A-150C arranged circularly around a center portion, i.e., the electrode housing bowl 106 (not shown). The cross-sectional view of FIG. 4B and side view of FIG. 4C provides a clear illustration of the peripheral fence opening area 142, the middle fence opening area 144, and the central fence opening area 146. FIG. 4D provides a bottom view of the chamber liner 108. As shown in FIG. 4D, the bottom of the chamber liner 108 includes a plurality of fence openings 150A-150C arranged circularly around the electrode housing bowl 106 (not shown).

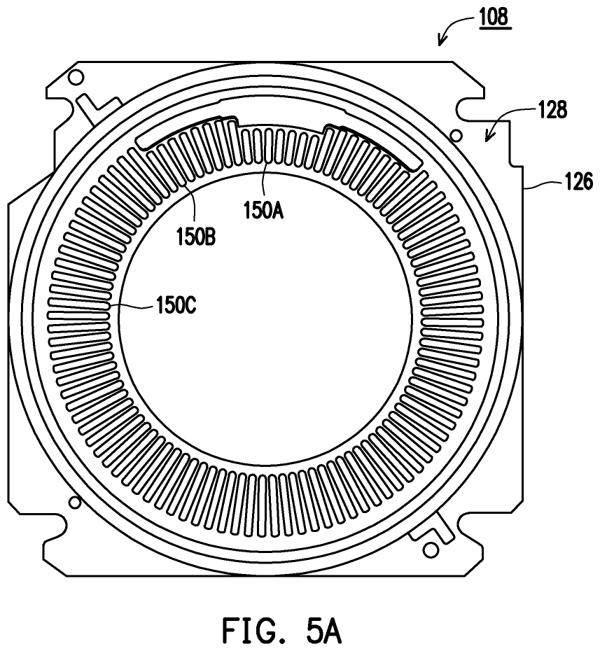

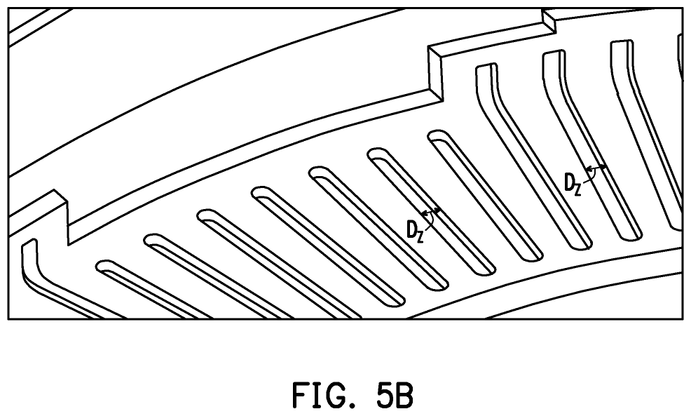

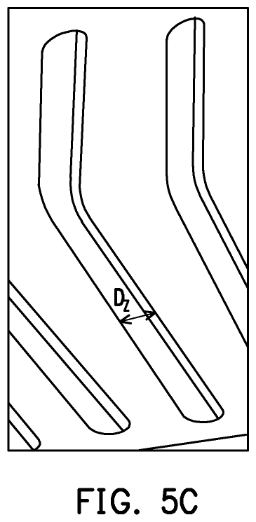

Turning now to FIGS. 5A-5C, there is shown a second embodiment of a chamber fence 200. As illustrated in FIG. 5A, each of a plurality of fence openings 202 are arranged circularly around a center portion, i.e., the electrode housing bowl 106 (not shown). As illustrated in FIGS. 5B and 5C, each opening 202 is implemented with a same width d_{z} 204. In such an embodiment, the width d_{z} 204 may be implemented in the range of about 0.1 mm to 100 mm.

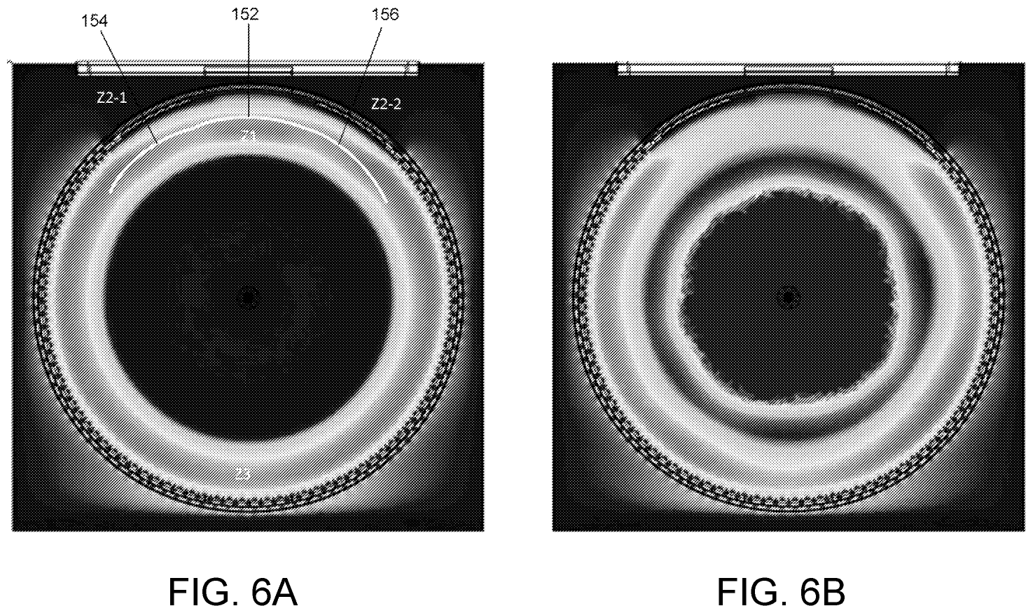

FIG. 6A provides an illustrative view of fluid flow within the process chamber 102 during processing operations utilizing the chamber liner 108 in accordance with one embodiment. As illustrated in FIG. 6A, the uniformity of the fluid flow within the process chamber 102 is readily apparent. That is, the variations in widths 160-164 of the openings 150A-150C provides a uniform passage of fluid (i.e. gas 112) through the chamber liner 108. Stated another way, the greater width of the openings 150A in Zone 1 (Z1) 160 alleviate issues occurring when uniform opening width is used by removing the deadzone that occurs below the split door 148 of the chamber liner 108. This results in improved wafer edge physical quality (e.g., profile, critical dimension, depth, etc.), polymer defect removal and wafer acceptance testing/chip probing (WAT/CP) yield enhancement, etc. In contrast, FIG. 6B provides an illustrative view of fluid flow within the process chamber 102 during processing operations utilizing the chamber liner 200 in accordance with the second embodiment illustrated in FIGS. 5A-5C. As shown in FIG. 6B, the uniformity of the fence openings 202 does not provide the uniform fluid flow shown using the chamber liner 108 in FIG. 6A.

Referring now to FIG. 7, there is shown an expanded view of the process semiconductor manufacturing apparatus 100 in accordance with one embodiment of the subject application. As shown in FIG. 7, the semiconductor manufacturing apparatus 100 comprises a process chamber 102, a chamber liner 108, and a power generating/control assembly 166 (e.g., a match unit, controller, etc.).

The process chamber 102 depicted in FIG. 7 may be, for example and without limitation, a chemical vapor deposition chamber, a sub-atmospheric pressure chemical vapor deposition chamber, a plasma enhanced chemical vapor deposition process chamber, plasma etching chamber, or other processing chambers used to deposit or etch dielectric, metal, or semiconductor layers on substrates. In accordance with one embodiment, the power generating assembly/control assembly 166 is any suitable match unit, e.g., radio frequency (RF) match, capable of providing suitable impedance control to ensure maximum radio frequency power is supplied to the process chamber 102 from an associated radio frequency generator. The power generating/control assembly 166 contains impedance matching circuitry tuned to facilitate coupling of both high frequency RF power from the RF generator and low frequency RF power from the RF generator to couple into the process chamber 102 with low impedance and minimal RF power loss or reflection. In some embodiments, the power generating/control assembly 166 may include one or more control elements, (e.g., a controller configured to control operations of the semiconductor manufacturing apparatus 100), including, for example and without limitation, a digital processor in communication with memory and one or more other disparate electronic devices. In such an implementation, the digital processor may be variously embodied, such as by a single core processor, a dual core processor (or more generally by a multiple core processor), a digital processor and cooperating math coprocessor, a digital controller, or the like. The digital processor, in addition to controlling the operation of the process chamber 102, executes instructions stored in memory for operating the semiconductor manufacturing apparatus 100. The aforementioned memory may represent any type of non-transitory computer readable medium such as random access memory (RAM), read only memory (ROM), magnetic disk or tape, optical disk, flash memory, or holographic memory.

In the illustrative example of FIG. 7, the electrode housing bowl 106 (e.g., electrostatic chuck) is coupled to the power generating/control assembly 116 via the cantilever 116. It will be appreciated that power and control to the electrode housing bowl 106 may be sent form the power generating/control assembly 166 through the cantilever 116. The electrode housing bowl 106 may be inserted into the process chamber 102 through a process chamber opening 168 located on one side of the process chamber 102. A seal 170 is positioned between the power generating/control assembly 166 and the process chamber 102 to ensure atmospheric integrity of the chamber 102 during operations thereof. After coupling of the power generating/control assembly 166 with the process chamber 102, the chamber liner 108 is positioned within the process chamber 102.

As shown in FIG. 7, the outer flange 126 of the chamber liner 108 is configured to engage the top of the process chamber 102 and may be secured thereto via suitable attachment mechanisms. Suitable attachment mechanisms include, for example and without limitation, screws, nuts, bolts, friction means, or the like. In some embodiments, one or more guides 172 are positioned on the top of the process chamber 102 to engage holes 174 on the outer flange 126. In such an embodiment, the guides 172 align the chamber liner 108 in the proper position prior to securing the attachment mechanisms. That is, the guides 172 may be configured to ensure the chamber liner 108 is properly positioned with the central fence opening area 146 and split door 148 aligned with a wafer input slot 176. In accordance with some embodiments, the wafer input slot 176 may include an automated door (not shown) allowing a robotic arm or other assembly to transit into and out of the process chamber 102. Such an assembly (not shown) may be configured to transport a wafer 104 into and out of the process chamber 102. Further, it will be appreciated from the illustration in FIG. 7 that the inner sidewall 138 is suitably configured to surround the electrode housing bowl 106 within the process chamber 102, thereby ensuring that the wafer 104 is correctly centered within the chamber liner 108 on the electrode housing bowl 106 and properly aligned with the wafer input slot 176. Accordingly, it will be appreciated that the illustration in FIG. 7 of the chamber liner 108 is to illustrate the split door 148 and the chamber liner 108 is suitably rotated prior to insertion to align the split door 148 with the wafer input slot 176 to allow ingress and egress of the wafer 104. One or more gas inlets 110A-C are positioned on the process chamber 102, providing an inlet for gas 112 to enter into the chamber 102.

Referring now to FIG. 8, there is shown a three-dimensional cut-away view of the chamber liner 108 within the process chamber 102 in accordance with some embodiments. As previously discussed above with respect to FIG. 7, the chamber liner 108 has been positioned so as to align the split door 148 with the wafer input slot 176 located on one sidewall 118 of the process chamber 102. FIG. 8 further illustrates the guide 172 extending through the guide hole 174 of the outer flange 126 of the chamber liner 108 to properly align the chamber liner 108 prior to securing the chamber liner 108 with the outer walls 118 of the process chamber 102. One or more fasteners are then used to secure the chamber liner 108 to the process chamber 102.

As illustrated in FIG. 8, the inner sidewall 138 is positioned adjacent the electrode housing bowl 106. FIG. 8 further illustrates the positioning of the chamber liner 108 relative to the cantilever 116, located opposite the wafer input slot 176 within the process chamber 102. It will be appreciated that the positioning of the cantilever 116 in FIG. 8 is intended as an illustration of one possible location thereof, and other process chambers 102 may have the cantilever 116 located in a different location relative to the wafer input slot 176. Additionally, the skilled artisan will appreciate that the wafer input slot 176 may be positioned at a different location on the process chamber 102, e.g., perpendicular to the cantilever 116, etc. In such other embodiments, the skilled artisan will appreciate that the split door 148 and thus the orientation of the chamber liner 108 within the process chamber 102 may be altered so as to align the split door 148 with the wafer input slot 176.

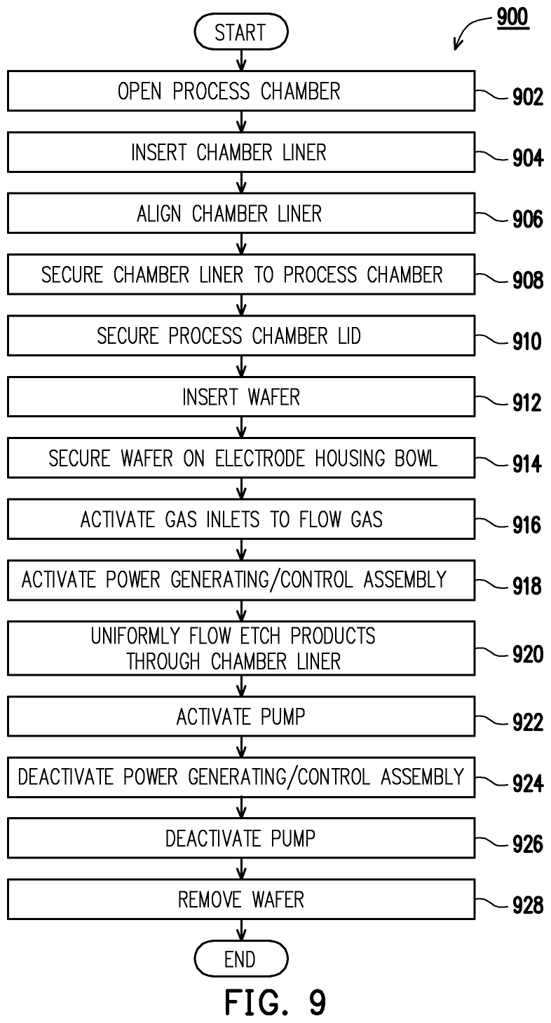

Referring now to FIG. 9, there is shown a flowchart illustrating a method 900 for processing a wafer 104 utilizing a chamber liner 108 in accordance with some embodiments. The method begins at 902, whereupon a lid (not shown) is removed or opened on the process chamber 102. It will be appreciated that the removal or opening of the lid may utilize automated procedures in accordance with the type of process chamber utilized and configuration thereof.

At 904, the chamber liner 108 having the progressive fence 140 in accordance with on embodiment is inserted into the process chamber 102. The chamber liner 108 is then aligned at 906 with the top of the process chamber 102 utilizing one or more guides 172 on the process chamber and guide holes 174 on the outer flange 126 of the chamber liner 108. In accordance with some embodiments, the alignment of the chamber liner 108 may include rotating the chamber liner 108 so as to align the split door 148 with the wafer input slot 176.

The chamber liner 108 is then secured to the top of the process chamber 102 at 908 using one or more fasteners (not shown) through the outer flange 126 of the chamber liner 108. At 910, the lid (not shown) is then secured to the top of the process chamber 102, thereby enclosing the process chamber 102 with the chamber liner 108 positioned therein. At 912, a wafer 104 is inserted into the process chamber 102 through the wafer input slot 176 of the sidewall 118 of the process chamber 102 and through the split door 148 of the chamber liner 108. The wafer 104 is then secured on the electrode housing bowl 106 at 914. In some embodiments, the electrode housing bowl 106 utilizes and electrostatic chuck that secures the wafer 104 in position within the process chamber 102.

At 916, gas inlets 110A-110C are activated to flow a gas 112 into the process chamber 102. The gas 112 may include, for example and without limitation, CₓH_{y}F_{z} (x,y,z): 0˜6, He, Ar, F₂, Cl₂, O₂, N₂, H₂, HBr, HF, NF₃, SF₆, or the like. The power generating/control assembly 166 then activates so as to supply, at 918, suitable RF frequency to the process chamber 102, thereby generating plasma 114 within the chamber 102. Etching products 122 then uniformly flow within the process chamber 102 through the chamber liner fence 140 to the bottom 120 of the process chamber 102 at 920. Examples of such etch products 122, may include, for example and without limitation FCN, Coₓ, (x: 1˜2), SiCl (x: 1˜4), SiFₓ (x: 1˜4). The pump 124 is then activated at 922 to extract, i.e., remove, these etch products 122 from the process chamber 102, resulting in a wafer 104 having improved edge physical quality (i.e., profile, critical dimensions, depth), polymer defect removal, and enhancement of wafer acceptance testing/chip probing.

At 924, the gas inlets 110A-110C and power generating/control assembly 166 deactivate to cease plasma generating operations within the process chamber 102. The pump 124 completes evacuation of the etch products 122 at 926, whereupon deactivation of the pump 124 occurs. At 928, the wafer 104 is removed from the process chamber 102 through the split door 148 of the chamber liner 108 and the wafer input slot 176 of the process chamber 108.

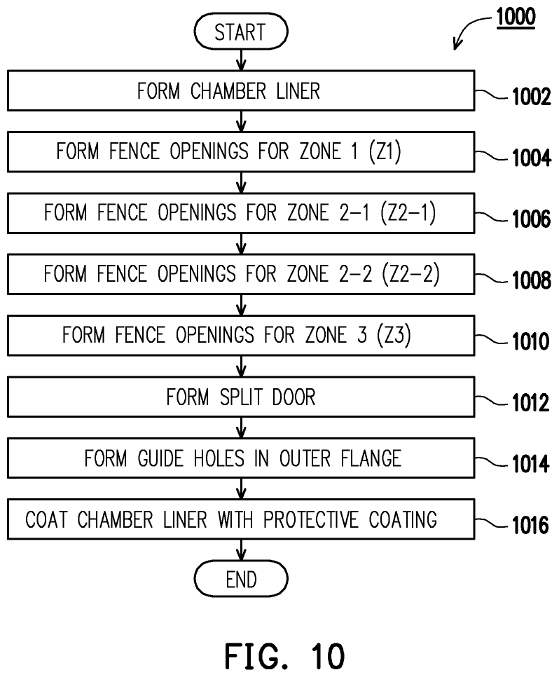

Turning now to FIG. 10, there is shown a flowchart illustrating a method 1000 for forming the progressive chamber liner fence 140 of a chamber liner 108 in accordance with some embodiments. The method 1000 begins at 1002, a chamber liner 108 is formed of a suitable material, the chamber liner 108 including a flat outer flange 126 adjacent an outer sidewall 136 and having an inner sidewall 138, wherein the outer sidewall 136 has a larger circumference than the inner sidewall 138. In accordance with some embodiments, the chamber liner 108 is formed of anodized aluminum, which may be stamped, molded, milled, or cast into the chamber liner 108.

Operations then proceed to 1004, whereupon a plurality of fence openings 150A corresponding to a first zone (Zone Z1 152) are formed (e.g., cut, stamped, etc.) on the chamber liner 108. At 1006, a plurality of fence openings 150B corresponding to a second zone (Zone Z2−1) 154 are formed (e.g., cut, stamped, etc.) on the chamber liner 108 adjacent a first side of the first zone (Z1) 152. At 1008, a plurality of fence openings 150B corresponding to a second zone (Zone Z2−2) 156 are formed (e.g., cut, stamped, etc.) on the chamber liner 108 adjacent second side of the first zone (Z1) 152. At 1010, a plurality of fence openings 150C corresponding to a third zone (Zone Z3) 158 are formed (e.g., cut, stamped, etc.) on the chamber liner 108 in between the Zone Z2−1 154 and Zone Z2−2 156. At 1012, a split door 148 is formed (e.g., cut, stamped, etc.) into the outer sidewall 136 of the chamber liner 108 above the first zone (Z1) 152 and the second zones Zone Z2−1 154 and Zone Z2−2 156. At least one guide hole 174 is then formed on the outer flange 126, e.g., drilled, stamped, cut, etc. at 1014. Thereafter, the chamber liner 108 is coated at 1016 with a protective coating, e.g., a Y-coat, including for example and without limitation, YF₃, YOF, YAG (Y₃Al₅O₁₂), or the like.

In accordance with a first embodiment, there is provided a chamber liner for a semiconductor process chamber. The chamber liner includes an outer sidewall having a first circumference, and an inner sidewall have a second circumference that is less than the first circumference. The chamber liner also includes a chamber liner fence that is positioned between the outer sidewall and the inner sidewall. The chamber liner fence includes a first zone having one or more first zone openings, a second zone having one or more second zone openings, and a third zone having one or more third zone opening. The chamber liner further includes a split door positioned in the outer sidewall.

In accordance with a second embodiment, there is provided a method for processing a semiconductor wafer. The method includes inserting a chamber liner into a process chamber, with the chamber liner including a chamber liner fence. The method also includes aligning the chamber liner within the process chamber, and securing the chamber liner to the process chamber. The method further includes inserting a wafer into the process chamber, and activating one or more gas inlets to flow gas into the process chamber. The method also includes activating a power generating assembly to generate plasma within the process chamber, and uniformly flowing an etch product through the chamber liner. In addition, the method includes activating a pump to remove the uniformly flowing etch product from the process chamber.

In accordance with a third embodiment, there is provided a method for forming a progressive chamber liner fence of a chamber liner. The method begins by forming a chamber liner, including an outer flange, an outer sidewall and an inner sidewall, with the outer sidewall having a circumference greater than a circumference of the inner sidewall. The method also includes forming fence openings corresponding to a first zone on the chamber liner. Additionally, the method includes forming fence openings corresponding to a first portion of a second zone on the chamber liner, with these fence openings corresponding to the first portion of the second zone being formed on a first side of the first zone. The method also includes forming fence openings corresponding to a second portion of the second zone on the chamber liner, with these fence openings corresponding to the second portion of the second zone being formed on a second side of the first zone. In addition, the method includes forming a fence openings corresponding to a third zone on the chamber liner, with these fence openings corresponding to the third zone being formed between the first portion of the second zone and the second portion of the second zone. The method further includes forming a split door in the outer sidewall of the chamber liner. The split door is positioned above the first zone, the first portion of the second zone, and the second portion of the second zone.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chamber liner for a semiconductor process chamber, comprising:
an outer sidewall having a first circumference;
an inner sidewall having a second circumference less than the first circumference;
a chamber liner fence disposed between the outer sidewall and the inner sidewall, the chamber liner fence including a first zone comprising at least one first zone opening, a second zone comprising at least one second zone opening, and a third zone comprising at least one third zone opening; and
a split door positioned in the outer sidewall.

2. The chamber liner of claim 1, wherein the at least one first zone opening has a width aₓ, the at least one second zone opening has a width by, and the at least one third zone opening has a width c_{z}, wherein c_{z}<by ≤aₓ.

3. The chamber liner of claim 2, wherein the second zone comprises a first portion and a second portion, and wherein the first zone is positioned between the first portion and the second portion.

4. The chamber liner of claim 3, wherein the first zone and the second zone are positioned below the split door.

5. The chamber liner of claim 4, wherein the widths aₓ, b_{y}, and c_{z}, are within the range of 0.1 mm to 100 mm.

6. The chamber liner of claim 1, further comprising an outer flange configured to secure the chamber liner to the semiconductor process chamber.

7. The chamber liner of claim 6, wherein the outer flange further comprises at least one guide hole configured to receive an associated guide of the semiconductor process chamber.

8. The chamber liner of claim 7, wherein the inner sidewall, the outer sidewall, the chamber liner fence and the outer flange are anodize aluminum.

9. The chamber liner of claim 8, wherein the chamber liner is coated with a protective coating.

10. The chamber liner of claim 1, wherein the inner sidewall is configured to surround an electrode housing bowl of the semiconductor process chamber.

11. A method for processing a semiconductor wafer, comprising:
inserting a chamber liner into a process chamber, the chamber liner including a chamber liner fence;
aligning the chamber liner within the process chamber;
securing the chamber liner to the process chamber;
inserting a wafer into the process chamber;
activating at least one gas inlet to flow gas into the process chamber;
activating a power generating assembly to generate plasma within the process chamber;
uniformly flowing an etch product through the chamber liner; and
activating a pump to remove the uniformly flowing etch product from the process chamber.

12. The method of claim 11, wherein the chamber liner fence comprises a first zone comprising at least one first zone opening, a second zone comprising at least one second zone opening, and a third zone having comprising at least one third zone opening.

13. The method of claim 12, wherein the at least one first zone opening has a width aₓ, the at least one second zone opening has a width b_{y}, and the at least one third zone opening has a width c_{z}, wherein c_{z}<b_{y}≤aₓ.

14. The method of claim 13, wherein the second zone comprises a first portion and a second portion, and wherein the first zone is positioned between the first portion and the second portion.

15. The method of claim 14, wherein the chamber liner further comprises a split door positioned above the first zone and the second zone, and wherein aligning the chamber liner further comprises aligning the split door with a wafer input slot of the process chamber.

16. The method of claim 15, wherein inserting the wafer further comprises inserting the wafer through wafer input slot and the split door of the chamber liner.

17. The method of claim 16, further comprising securing wafer to an electrode housing bowl within the process chamber.

18. A method for forming a progressive chamber liner fence of a chamber liner, comprising:
forming a chamber liner, including an outer flange, the chamber liner including an outer sidewall and an inner sidewall, the outer sidewall having a circumference greater than a circumference of the inner sidewall;
forming a plurality of fence openings corresponding to a first zone on the chamber liner;
forming a plurality of fence openings corresponding to a first portion of a second zone on the chamber liner, the plurality of fence openings corresponding to the first portion of the second zone formed on a first side of the first zone;
forming a plurality of fence openings corresponding to a second portion of the second zone on the chamber liner, the plurality of fence openings corresponding to the second portion of the second zone formed on a second side of the first zone;
forming a plurality of fence openings corresponding to a third zone on the chamber liner, the plurality of fence openings corresponding to the third zone formed between the first portion of the second zone and the second portion of the second zone; and
forming a split door in the outer sidewall of the chamber liner, the split door positioned above the first zone, the first portion of the second zone, and the second portion of the second zone.

19. The method of claim 18, wherein the plurality of fence openings corresponding to the first zone each have a width aₓ, the plurality of fence openings corresponding to the first and second portions of the second zone each have a width by, and the plurality of fence openings corresponding to the third zone each has a width c_{z}, and wherein c_{z}<b_{y}≤aₓ.

20. The method of claim 19, further comprising forming at least one guide hole on the outer flange, the at least one guide hole configured to receive a corresponding at least one guide of an associated process chamber.
